(19) United States
(12) Patent Application Publication
(10) Pub. No.: US 2026/0032975 A1
(43) Pub. Date: Jan. 29, 2026

(54) DIODE STRUCTURE AND METHOD OF MANUFACTURE

(71) Applicant: TEXAS INSTRUMENTS INCORPORATED, Dallas, TX (US)

(72) Inventors: Siva Devireddy, Fremont, CA (US); Archana Venugopal, Mountain View, CA (US); Fanchi Hou, Frisco, TX (US); Natalia Lavrovskaya, Sunnyvale, CA (US); Alexei Sadovnikov, Sunnyvale, CA (US)

(21) Appl. No.: 18/782,446

(22) Filed: Jul. 24, 2024

(51) Int. Cl. H01L 29/06; H01L 29/66; H01L 29/866

(52) U.S. Cl. CPC H10D 62/125; H10D 8/022; H10D 8/25

(57) ABSTRACT

The present disclosure generally relates to a semiconductor device including a p-n junction formed in part by a Zener region. In an example, a semiconductor device includes first and second doped regions both in a semiconductor substrate. The first doped region is doped with a first conductivity type dopant. The first doped region is across first and second lateral regions. The second doped region is doped with a second conductivity type dopant opposite from the first conductivity type dopant. The first and second doped regions form a p-n junction. The second doped region underlies the first doped region in the first lateral region. A peak concentration of the second conductivity type dopant is at a uniform depth across the first lateral region and intersects the first doped region in the second lateral region at a lateral distance from a transition between the first and second lateral regions.

### BACKGROUND

A diode generally includes a p-n junction in a semiconductor substrate. When a voltage above a threshold voltage forward biases the diode, the diode conducts current with little voltage drop. In some circumstances, some diodes may conduct current when reverse biased with a sufficient voltage. An electrical breakdown may occur when sufficient reverse bias is applied to the p-n junction, which may permit the diode to conduct current.

### SUMMARY

An example described herein is a semiconductor device. The semiconductor device includes a first doped region in a semiconductor substrate and a second doped region in the semiconductor substrate. The first doped region is doped with a first conductivity type dopant. The first doped region is across a first lateral region and a second lateral region. The second doped region is doped with a second conductivity type dopant opposite from the first conductivity type dopant. The first doped region and the second doped region form a p-n junction. The second doped region underlies the first doped region in the first lateral region. A peak concentration of the second conductivity type dopant is at a uniform depth across the first lateral region. The peak concentration of the second conductivity type dopant intersects the first doped region in the second lateral region at a lateral distance from a transition between the first lateral region and the second lateral region.

Another example is a semiconductor device. The semiconductor device includes a first doped region in a semiconductor substrate and a second doped region in the semiconductor substrate. The first doped region is doped with a first conductivity type dopant. The first doped region is across a first lateral region and a second lateral region. The second doped region is doped with a second conductivity type dopant opposite from the first conductivity type dopant. The second doped region underlies the first doped region in the first lateral region. A peak concentration of the second conductivity type dopant is uniform in depth in the semiconductor substrate across the first lateral region. A first concentration of the second conductivity type dopant changes in depth in the semiconductor substrate throughout the second lateral region such that the peak concentration of the second conductivity type dopant decreases in depth in the semiconductor substrate in the second lateral region and in a direction laterally away from the first lateral region. The first lateral region has a radius. The second lateral region has a lateral dimension aligned with the radius. The lateral dimension is equal to or greater than 0.02 μm.

A further example is a method. A first doped region is formed in a semiconductor substrate. The first doped region is doped with a first conductivity type dopant. A second doped region is formed in the semiconductor substrate. The second doped region is doped with a second conductivity type dopant opposite from the first conductivity type dopant. The second doped region underlies the first doped region. Forming the second doped region includes forming a photoresist over the semiconductor substrate and implanting the second conductivity type dopant into the semiconductor substrate using the photoresist as a mask. The photoresist has a first opening defined at least in part by a first sidewall. At least a portion of the first sidewall is sloped at a first angle of 80 degrees or less to a plane parallel to an upper surface of the semiconductor substrate.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a layout view of a semiconductor device according to some examples.

FIGS. 2A and 2B illustrate cross-sectional views of a semiconductor device like in

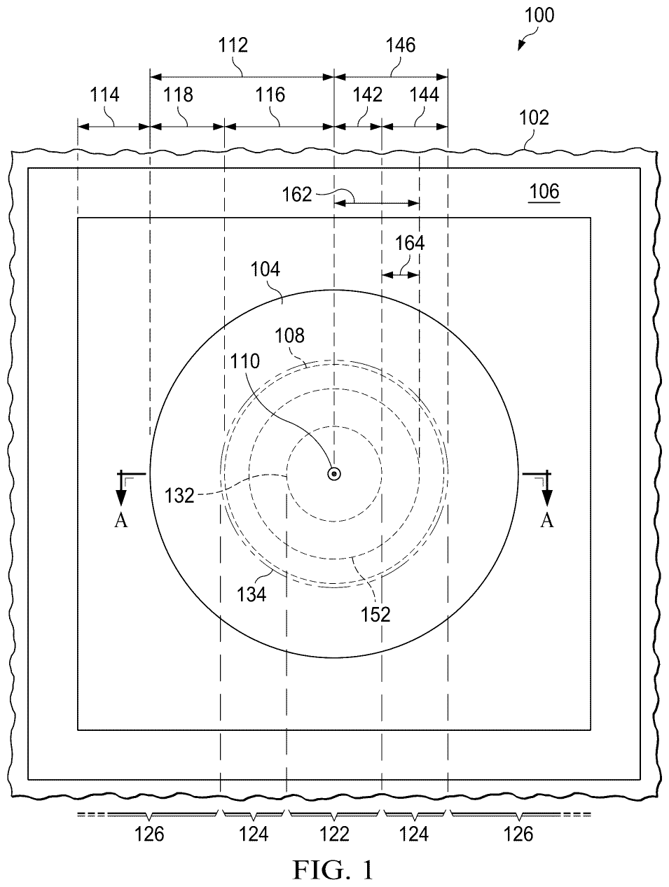

FIG. 1 for forming a Zener region according to some examples.

FIGS. 3A and 3B illustrate cross-sectional views of a semiconductor device like in FIG. 1 for forming a Zener region according to some examples.

FIGS. 4A, 4B, and 4C are charts illustrating concentrations of p-type dopants that form a Zener region and n-type dopants that form a cathode region according to some examples.

FIG. 5 is a layout view of a semiconductor device according to some examples.

FIG. 6 illustrates a cross-sectional view of the semiconductor device of FIG. 5 for forming multiple Zener regions according to some examples.

FIGS. 7, 8, 9, and 10 are respective cross-sectional views of a semiconductor device in intermediate stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to a semiconductor device including a p-n junction that exhibits tunneling breakdown characteristics (which may also be referred to as Zener breakdown or Zener effect) under a reverse bias condition. Such a p-n junction may include a metallurgical junction between an n-type doped region and a p-type doped region with a relatively high dopant concentration at the metallurgical junction such that reverse bias electric field across the p-n junction may be approximately 3×107 V/m or greater. The p-n junction may be regarded to be formed in part by a Zener region described hereinafter. In some examples of the present disclosure, a semiconductor device (e.g., a diode) includes an n-type doped cathode region and a p-type doped Zener region in a semiconductor substrate. The semiconductor device may also include a p-type doped anode region in the semiconductor substrate. The Zener region may have a p-type dopant profile that exhibits primarily tunneling breakdown characteristics (as opposed to impact ionization breakdown characteristics) under a reverse bias condition that results in a desirable noise property. The p-type dopant profile of the Zener region may be achieved by using a photoresist having an opening defined by a sidewall, at least a portion of which is sloped, as a mask to implant the p-type dopant. Other benefits and advantages may be achieved.

Various examples described below are described in the context of concentrations, peak concentrations, and slopes of concentrations (e.g., peak concentrations). These concentrations are described as understood to represent a general trend or rolling average of a concentration (e.g., dopant concentration) within a semiconductor device, as opposed to a noisy signal response representing a concentration that may be detected by, for example, secondary ion mass spectrometry (SIMS).

Further, various examples of the present disclosure are described in the context of a cathode region, anode region, and Zener region that are doped with specified dopant conductivity types (e.g., n-type and p-type). In some examples, the cathode region (e.g., doped with n-type dopants) may be replaced by an anode (e.g., doped with p-type dopants) and vice versa, and the Zener region may be doped with an opposite conductivity type from what is specifically described herein.

Various examples are described subsequently. Although the specific examples may illustrate various aspects of the above generally described features, examples may incorporate any combination of the above generally described features (which are described in more detail in examples below).

FIG. 1 is a layout view of a semiconductor device 100 according to some examples. The semiconductor device 100 may be a diode. The semiconductor device 100 is in a semiconductor substrate 102. The semiconductor device 100 includes a cathode region 104 (e.g., a region exposed, during a respective implantation to form the cathode region 104, by a photoresist with a substantially vertical sidewall to receive an n-type dopant), an anode region 106 (e.g., a region exposed, during a respective implantation to form the anode region 106, by a photoresist with a substantially vertical sidewall to receive a p-type dopant), and a Zener region 108 (e.g., a region exposed, during a respective implantation to form the Zener region 108, by a photoresist with a sidewall, at least a portion of which is sloped, to receive a p-type dopant).

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as the semiconductor device 100, are formed. In some examples, the semiconductor material is or includes silicon (Si), silicon germanium (SiGe), gallium arsenide (GaAs), gallium nitride (GaN), the like, or a combination thereof. The semiconductor substrate 102 has a surface (e.g., an upper surface) in and/or on which devices are formed. Depths in the semiconductor substrate 102 described herein are in reference to this upper surface (e.g., a depth in the semiconductor substrate 102 from the upper surface of the semiconductor substrate 102). In the illustrated example, the semiconductor material of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

The cathode region 104, in some examples, is an n-type doped region in the semiconductor substrate 102. The cathode region 104, as illustrated, has a circular shape in the layout with a half lateral dimension 112 (e.g., a radius) from a center 110 of the cathode region 104, which half lateral dimension 112 may be a largest half lateral dimension for another implemented shape of the cathode region 104. In some examples, the half lateral dimension 112 is in a range from 1 μm to 50 μm, such as 2 μm. The cathode region 104 extends from an upper surface of the semiconductor substrate 102 to a depth in the semiconductor substrate 102. As detailed later in FIGS. 4A, 4B, and 4C, a peak concentration of the n-type dopant of the cathode region 104 is at or near the upper surface of the semiconductor substrate 102, and a concentration of the n-type dopant of the cathode region 104 decreases from the peak concentration of the n-type dopant towards greater depths in the semiconductor substrate 102. In some examples, the cathode region 104 is doped with an n-type dopant (e.g., phosphorus (P) or arsenic (As)) with a peak concentration in a range from 1×10¹⁹ cm⁻³ to 1×10²¹ cm⁻³. Another doping concentration may be implemented. The shape of the cathode region 104 in a layout may differ in other examples, such as being rectangular (e.g., a square), ovaloid, or another shape.

The anode region 106, in some examples, is a p-type doped region in the semiconductor substrate 102. The anode region 106, as illustrated, has a rectangular shape in the layout. The anode region 106 laterally surrounds the cathode region 104. A lateral dimension 114 is between the cathode region 104 and the anode region 106, and as shown in the illustrated example, the lateral dimension 114 is a minimum or smallest lateral dimension between the cathode region 104 and the anode region 106. In some examples, the lateral dimension 114 is in a range from 0.5 μm to 2 μm, such as 0.8 μm. A lateral dimension between the cathode region 104 and the anode region 106 may vary depending on the cross-section in which the lateral dimension is measured, which may result from differing shapes of the cathode region 104 and the anode region 106 in the layout. The anode region 106 extends from an upper surface of the semiconductor substrate 102 to a depth in the semiconductor substrate 102. In some examples, the anode region 106 is doped with a p-type dopant (e.g., boron (B)) with a concentration in a range from 1×10¹⁹ cm⁻³ to 1×10²¹ cm⁻³. Another doping concentration may be implemented. The shape of the anode region 106 in a layout may differ in other examples, such as being circular, ovaloid, or another shape.

The Zener region 108, in some examples, is a p-type doped region in the semiconductor substrate 102. The Zener region 108, as illustrated, has a circular shape in the layout with a half lateral dimension 116 (e.g., a radius) from the center 110 of the cathode region 104, which is also a center of the Zener region 108. The half lateral dimension 116 may be a largest half lateral dimension for another implemented shape of the Zener region 108. In some examples, the half lateral dimension 116 is in a range from 1 μm to 50 μm, such as 2 μm. The Zener region 108 is laterally within the cathode region 104 in the layout view (a top-down view). The cathode region 104 laterally surrounds or encircles and extends laterally from the Zener region 108 by a lateral dimension 118. In some examples, the lateral dimension 118 is in a range from 0.5 μm to 2 μm, such as 1 μm. Hence the half lateral dimension 112 of the cathode region 104 is equal to a sum of the half lateral dimension 116 of the Zener region 108 and the lateral dimension 118. In an example, the half lateral dimension 112, the half lateral dimension 116, and the lateral dimension 118 correspond to 10 μm, 9 μm, and 1 μm, respectively. In another example, the half lateral dimension 112, the half lateral dimension 116, and the lateral dimension 118 correspond to 20 μm, 19 μm, and 1 μm, respectively. In yet another example, the half lateral dimension 112, the half lateral dimension 116, and the lateral dimension 118 correspond to 50 μm, 49 μm, and 1 μm, respectively.

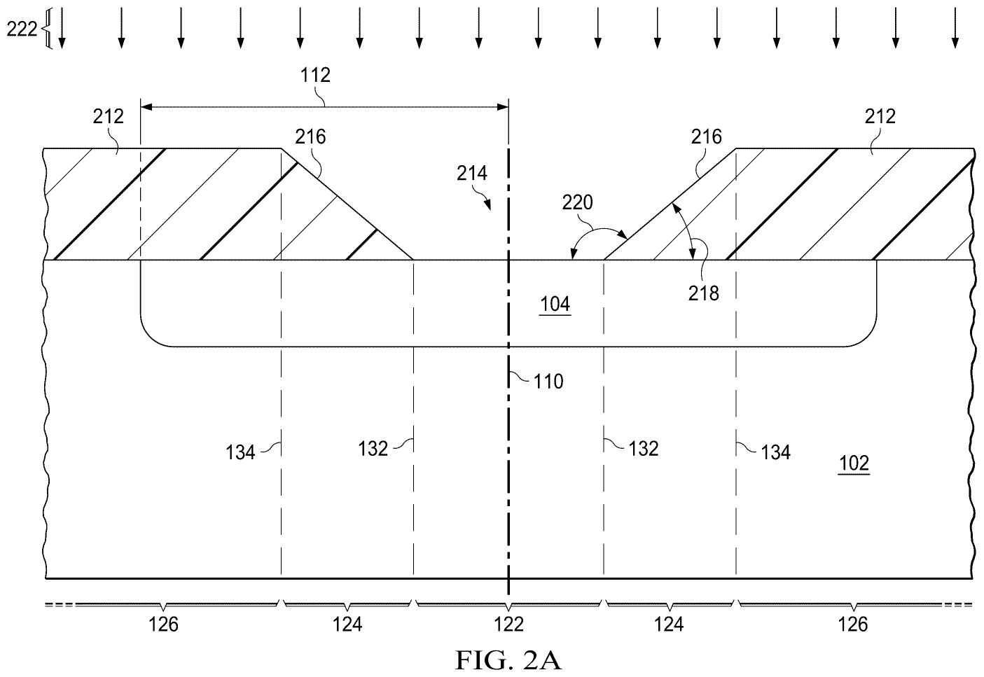

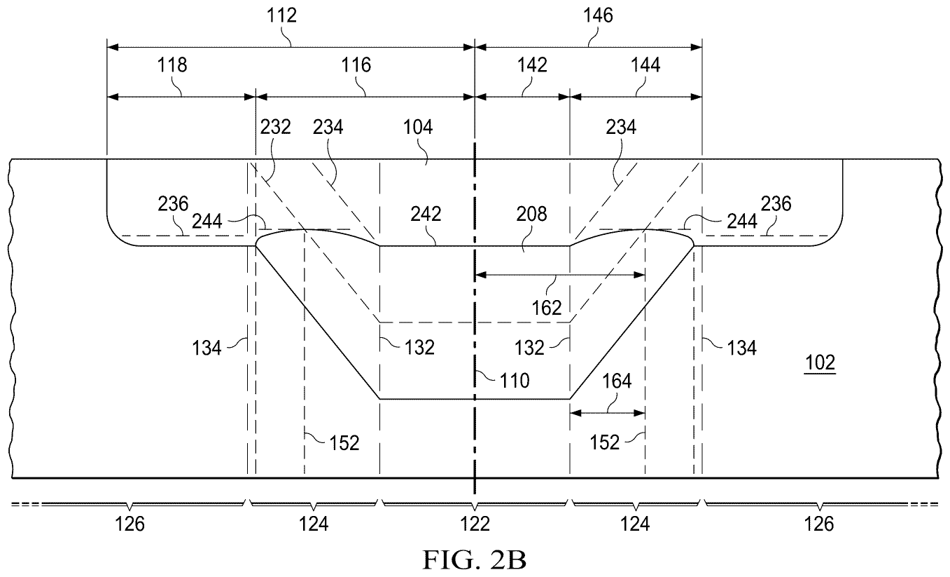

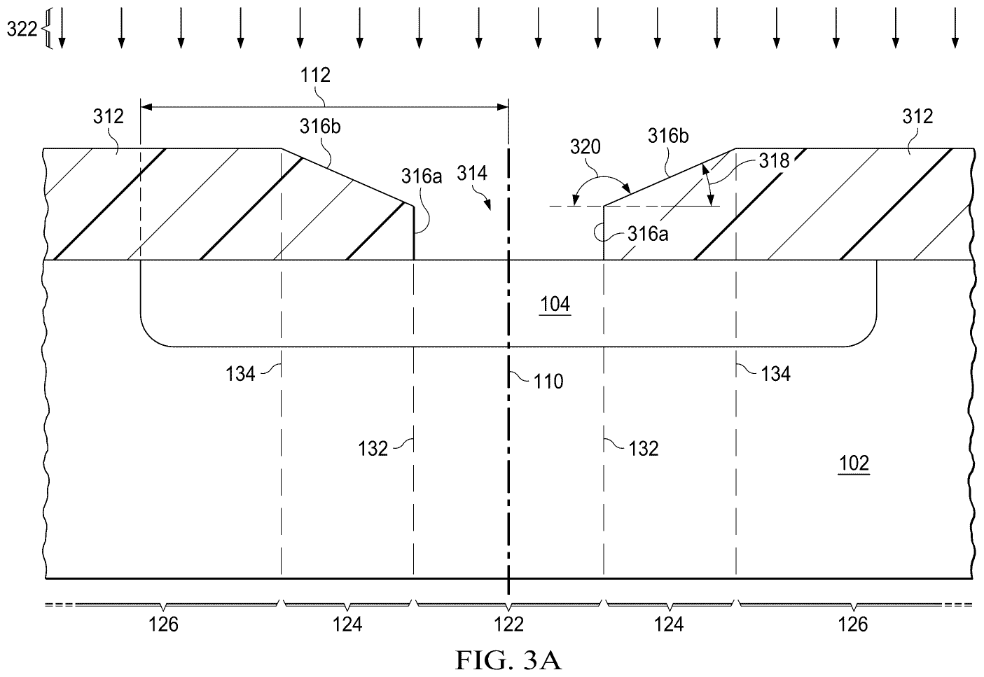

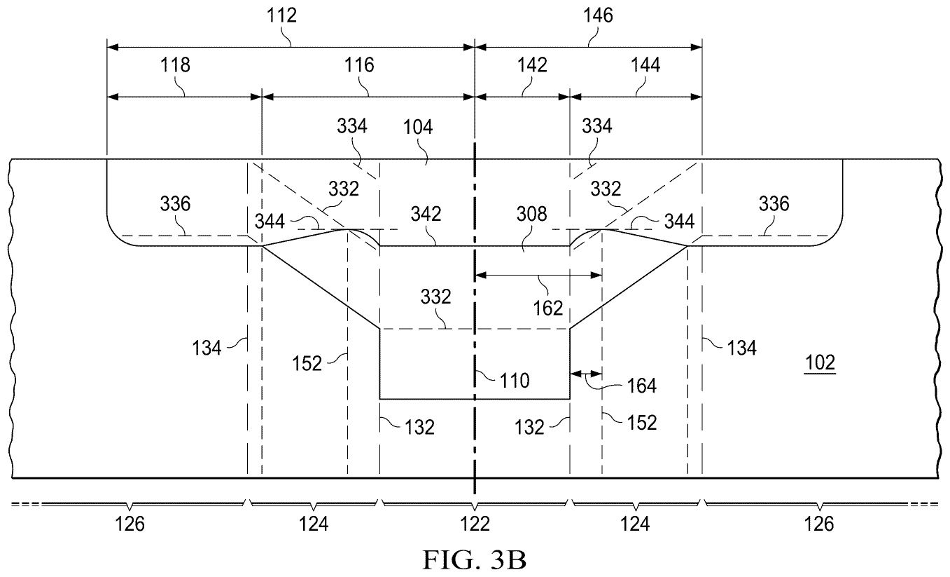

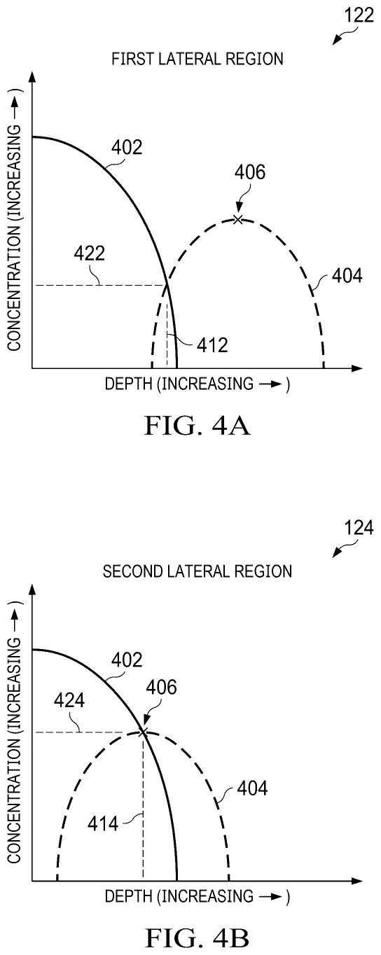

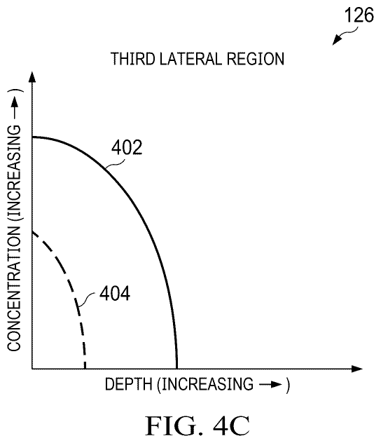

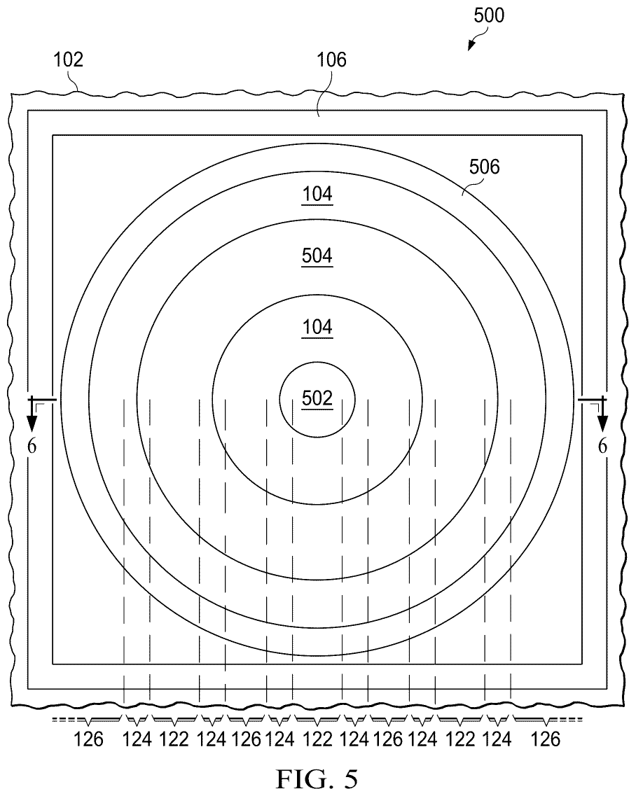

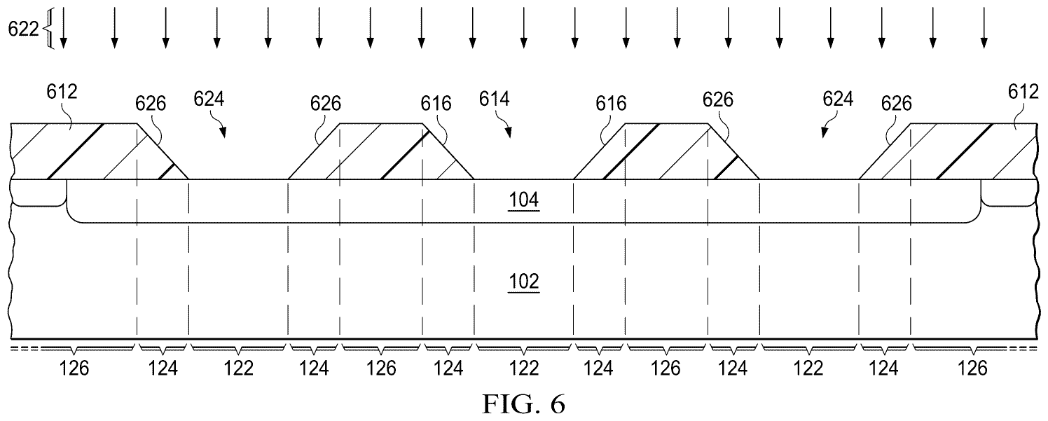

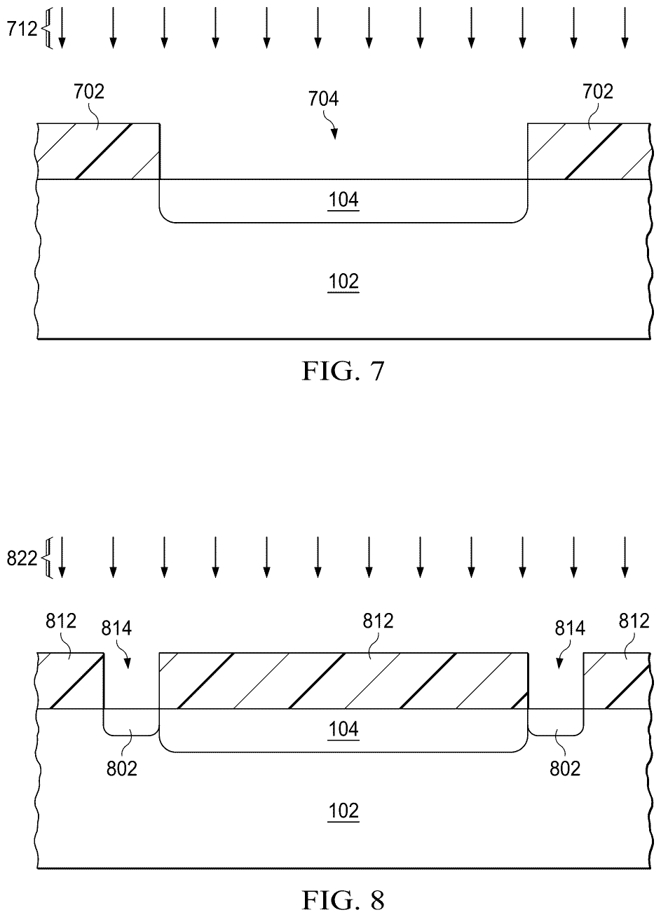

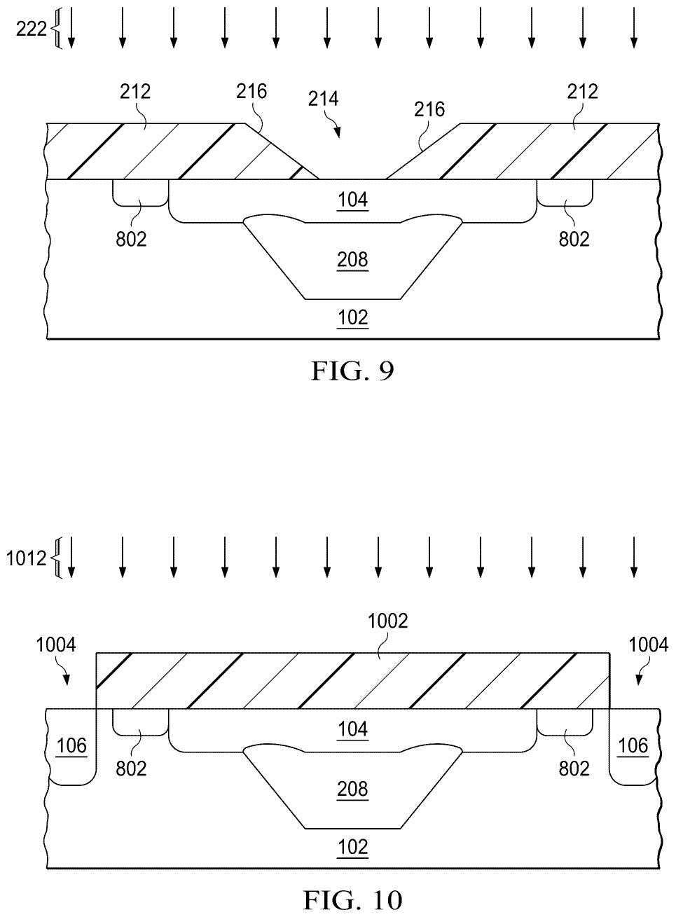

The Zener region 108 underlies the cathode region 104 in the semiconductor substrate 102 (e.g., as shown in FIGS. 2B, 3B, 4A, and 4B) and extends from the cathode region 104 to a depth in the semiconductor substrate 102. As detailed later, a peak concentration of the p-type dopant of the Zener region 108 may be controlled to be at various depths in the semiconductor substrate 102. Controlling the depth of the peak concentration of the p-type dopant of the Zener region 108 may facilitate the semiconductor device 100 to exhibit primarily tunneling breakdown characteristics (as opposed to impact ionization breakdown characteristics) under a reverse bias condition resulting in a desired noise property of the semiconductor device 100. In other words, reverse bias breakdown characteristics (e.g., current versus voltage characteristics) of the semiconductor device 100 are primarily determined (e.g., dominated, prevailed) by tunneling current portion even if other current portion (e.g., impact ionization current, avalanche current) may be present. In some examples, the Zener region 108 is doped with a p-type dopant with a peak concentration in a range from 3×10¹⁸ cm⁻³ to 3×10¹⁹ cm⁻³. Another doping concentration may be implemented. The shape of the Zener region 108 in a layout may differ in other examples, such as being rectangular (e.g., a square), ovaloid, or another shape.

A concentration (e.g., the peak concentration) of the p-type dopant of the Zener region 108 is greater than a concentration of the p-type dopant of the semiconductor substrate 102. Similarly, a concentration (e.g., a peak concentration) of the p-type dopant of the anode region 106 is greater than a concentration of the p-type dopant of the semiconductor substrate 102. A concentration (e.g., a peak concentration) of the n-type dopant of the cathode region 104 is greater than a concentration of the p-type dopant of the semiconductor substrate 102 and the concentration (e.g., the peak concentration) of the p-type dopant of the Zener region 108.

FIG. 1 further shows a first lateral region 122, a second lateral region 124, and a third lateral region 126. In the example semiconductor device 100, the second lateral region 124 is annular ring shaped laterally surrounding or encircling the first lateral region 122 in a top-down view. Further, in the example semiconductor device 100, the third lateral region 126 is laterally surrounding or encircling the second lateral region 124 in the top-down view. A first-second transition 132 is shown at a transition between the first lateral region 122 and the second lateral region 124. A second-third transition 134 is shown at a transition between the second lateral region 124 and the third lateral region 126. In other examples, the first lateral region 122 and second lateral region 124, and hence, the transitions 132, 134, may have different shapes in the top-down view based on, e.g., the shape of the Zener region 108. In a cross-section A-A illustrated in subsequent drawings, the second lateral region 124 is shown to have intersections in distinct areas, and the third lateral region 126 is shown to have intersections in distinct areas.

The cathode region 104 is laterally across the first lateral region 122 and the second lateral region 124 and extends into the third lateral region 126. The Zener region 108 is laterally across the first lateral region 122 and extends into the second lateral region 124. The Zener region 108 underlies the cathode region 104 in the first lateral region 122 and the second lateral region 124. The Zener region 108 does not underlie the cathode region 104 in the third lateral region 126.

The first lateral region 122 is an area of the semiconductor substrate 102 that is fully exposed (e.g., without photoresist blocking) during an implantation process to form the Zener region 108 (e.g., a Zener implantation). The third lateral region 126 is an area of the semiconductor substrate 102 that has full blocking, to the extent provided, by a photoresist during the implantation process to form the Zener region 108. The second lateral region 124 is an area of the semiconductor substrate 102 that experiences varying levels of blocking by the photoresist during the implantation process to form the Zener region 108—e.g., in view of the photoresist having a sidewall, at least a portion of which is sloped.

The peak concentration of the p-type dopant of the Zener region 108 may be at a uniform depth in the semiconductor substrate 102 across and throughout the first lateral region 122. The peak and/or another concentration of the p-type dopant of the Zener region 108 varies in depth in the semiconductor substrate 102 throughout the second lateral region 124, e.g., due to the partially blocked Zener implantation resulting in vertical shift of the implanted p-type dopant profile as a function of a lateral location in the second lateral region 124. In various examples, the peak concentration may be continuous or discontinuous at a transition from the first lateral region 122 to the second lateral region 124. In the third lateral region 126, the p-type dopant implanted to form the Zener region 108 may or may not be present depending on a full thickness of the photoresist used in the implantation.

For example, if the photoresist is sufficiently thick, no p-type dopant from the implantation may reach the semiconductor substrate 102 in the third lateral region 126. In such examples, the outer lateral boundary of the second lateral region 124, and hence, the second-third transition 134, is where measurable quantities of the p-type dopant from the Zener implantation cease to be present and/or are dominated by the concentration of p-type dopants of the semiconductor substrate 102. In other examples, where the full thickness of the photoresist permits at least a portion of the p-type dopant from the Zener implantation to reach the semiconductor substrate 102 in the third lateral region 126, the outer lateral boundary of the second lateral region 124, and hence, the second-third transition 134, is where a depth of a given concentration of the p-type dopant in the semiconductor substrate 102 transitions to a uniform depth through the third lateral region 126. Accordingly, the second-third transition 134 may be (i) where detectable quantities of the p-type dopant in the second lateral region 124 transitions to no detectable quantities of the p-type dopant and/or the p-type dopant is dominated by the concentration of p-type dopants of the semiconductor substrate 102 or (ii) where a depth of a given concentration of the p-type dopant (implanted to form the Zener region 108) in the semiconductor substrate 102 transitions to a uniform depth through the third lateral region 126.

The first lateral region 122 has a half lateral dimension 142 (e.g., a radius) from the center 110 (e.g., from the center 110 to the first-second transition 132), which half lateral dimension 142 may be a largest half lateral dimension for another shape of the first lateral region 122. The second lateral region 124 has a lateral dimension 144 from the first-second transition 132 to the second-third transition 134. The lateral dimension 144 is aligned (e.g., radially aligned from the center 110) with the half lateral dimension 142. A half lateral dimension 146 (e.g., radius) is from the center 110 to the second-third transition 134 and is the sum of the aligned half lateral dimension 142 and the lateral dimension 144. In some examples, the half lateral dimension 142 is in a range from 0.5 μm to 25 μm, such as 1 μm, and the lateral dimension 144 is in a range from 0.02 μm to 2 μm, such as 0.2 μm.

In the second lateral region 124, the depth of the peak concentration of the p-type dopant implanted to form the Zener region 108 decreases (e.g., becomes shallower) from the first-second transition 132 laterally away from the first lateral region 122. The decrease in the depth may be continuous or discontinuous. In some examples, the change in the depth of the peak concentration (e.g., the peak concentration depths) may be related to the shape (e.g., sidewall profile) of the photoresist used as a mask during the Zener implantation. In some examples, the decrease in depth of the peak concentration has a slope that has a magnitude less than or equal to 5.67, and more particularly, in a range from 1 to 5.67. In some examples, the peak concentration (and other concentrations) of the p-type dopant may have this slope over a portion of the lateral dimension 144 laterally from the first-second transition 132 (e.g., radially from the center 110), for example, over 50% or greater of the lateral dimension 144 from the first-second transition 132. In other examples, the peak concentration (and other concentrations) of the p-type dopant may have this slope over the entire lateral dimension 144 laterally from the first-second transition 132 (e.g., radially from the center 110).

A p-n junction is formed between the cathode region 104 and the Zener region 108. The p-n junction may be at depths where the n-type dopant concentration of the cathode region 104 is substantially equal to the p-type dopant concentration of the Zener region 108. A depth of the p-n junction is uniform throughout the first lateral region 122, such as at a first depth 412 depicted in FIG. 4A. A depth of the p-n junction may vary in the second lateral region 124. For example, the depth of the p-n junction may be initially shallower than the first depth 412 at locations laterally away (e.g., radially from the center 110) from the first-second transition 132. After reaching a shallowest depth (e.g., as depicted in FIG. 4B), the p-n junction may then become deeper in the semiconductor substrate 102 in the second lateral region 124 laterally away from (e.g., radially in a direction from the center 110) the shallowest depth.

Moreover, as described herein with reference to FIGS. 4A and 4B, the dopant concentrations at which the p-n junction forms increases in the second lateral region 124 in a direction from the first-second transition 132 when compared to the dopant concentrations at which the p-n junction forms in the first lateral region 122—e.g., FIG. 4B illustrating the p-n junction forming at the peak concentration of the p-type dopant introduced during the Zener implantation. Accordingly, a depletion layer width associated with the p-n junction in at least a portion of the second lateral region 124 may be generally less than a depletion layer width associated with the p-n junction in the first lateral region 122. As a result, the reverse bias breakdown behavior may be different between the first lateral region 122 and the second lateral region 124.

For example, the reverse bias breakdown behavior of the first lateral region 122 may be dominated by impact ionization phenomena at a first reverse bias voltage whereas the reverse bias breakdown behavior of the second lateral region 124 may be dominated by tunneling phenomena at a second reverse bias voltage less than the first reverse bias voltage—e.g., due to higher electric field stemming from the less depletion layer width in the second lateral region 124. As such, overall reverse bias breakdown behavior of the semiconductor device 100 may be primarily determined by the p-n junction characteristics of the second lateral region 124 in view of the less breakdown voltage. The tunneling phenomena may be less prone to generating noise than the impact ionization phenomena, and thus the semiconductor device 100 may exhibit less noisy characteristics during operations.

FIG. 1 shows a peak intersection 152 in the second lateral region 124 where the peak concentration of the p-type dopant of the Zener region 108 intersects the cathode region 104 and the p-n junction formed with the cathode region 104. The peak intersection 152 has a half lateral dimension 162 (e.g., a radius) from the center 110 (e.g., from the center 110 to the peak intersection 152), which half lateral dimension 162 may be a largest half lateral dimension for another implemented shape. The peak intersection 152 has a lateral dimension 164 (or a lateral distance 164), which is aligned with the half lateral dimension 162, from the first-second transition 132. In some examples, the half lateral dimension 162 (e.g., radius) and/or the lateral dimension 164 of the peak intersection 152 (e.g., where the tunneling phenomenon is prominent) in the second lateral region 124 relative to the half lateral dimension 112 (e.g., radius) of the cathode region 104 may further affect overall reverse bias breakdown characteristics (e.g., noise characteristics) of the semiconductor device 100. It may be desirable to have a larger half lateral dimension 162 (e.g., radius), and hence, larger lateral dimension 164, of the peak intersection 152 relative to the half lateral dimension 112 (e.g., radius) of the cathode region 104 such that overall reverse bias breakdown characteristics (e.g., noise characteristics) of the semiconductor device 100 may be primarily determined by the tunneling phenomena in the second lateral region 124, which may result in less noisy properties of the semiconductor device 100. In some examples, the half lateral dimension 162 is in a range from 0.5 μm to 25 μm, such as 1 μm. In some examples, the lateral dimension 164 is in a range from 0.01 μm to 1.8 μm, such as 0.1 μm.

FIGS. 2A and 2B illustrate cross-sectional views of a semiconductor device (e.g., the semiconductor device 100 through a cross-section A-A of FIG. 1) for forming a Zener region 208 according to some examples. FIGS. 2A and 2B show the semiconductor device during and following implantation of a p-type dopant for forming the Zener region 208 (e.g., a Zener implantation). Referring to FIG. 2A, the cathode region 104 has been formed in the semiconductor substrate 102. A photoresist 212 is formed over and on the semiconductor substrate 102. In some examples, the photoresist 212 has a thickness in a range from approximately 0.5 μm (e.g., 0.5 μm±10%, 0.5 μm±20%) to approximately 2 μm (e.g., 2 μm±10%, 2 μm±20%). The photoresist 212 has an opening 214 that exposes an upper surface of the semiconductor substrate 102. The opening 214 is defined by sloped sidewalls 216 of the photoresist 212. Each sloped sidewall 216 is sloped throughout the thickness of the photoresist 212 (e.g., from a bottom surface of the photoresist 212 to a top surface of the photoresist 212).

The portion of the upper surface of the semiconductor substrate 102 that is fully exposed by the opening 214 corresponds to the first lateral region 122. In this example, the lateral extents of the sidewalls 216 define the second lateral region 124. The third lateral region 126 is the region covered by the full thickness of the photoresist 212. In some examples, if full blocking of dopants in the Zener implantation may be achieved by a partial thickness of the photoresist 212, the third lateral region 126 may expand to include portions of the photoresist 212 forming the sidewalls 216 where the thickness of the photoresist 212 is at or exceeds the thickness to achieve full blocking.

The sloped sidewalls 216 form an angle 218 with the upper surface of the semiconductor substrate 102 (or a plane parallel to the upper surface) interior to the photoresist 212 and form an angle 220 with the upper surface of the semiconductor substrate 102 (or a plane parallel to the upper surface) interior to the opening 214. In some examples, the angle 218 interior to the photoresist 212 may be equal to or less than 80 degrees, and more particularly, in a range from 45 degrees to 80 degrees. In some examples, the angle 220 interior to the opening 214 may be equal to or greater than 100 degrees, and more particularly, in a range from 100 degrees to 135 degrees.

The photoresist 212 may be formed by depositing and patterning the photoresist 212 using appropriate photolithography techniques. To pattern the photoresist 212 with the opening 214 having the sloped sidewalls 216, in some examples, focus of the light used with constant exposure in the photolithography technique may be tuned. In some examples, with a fixed focus and exposure, a selective etching, plasma treatment, and/or ash process may be implemented to control the shape of the sidewalls 216. In some examples, photoresist shaping using an implant may be implemented to control the shape of the sidewalls 216.

Using the photoresist 212 as a mask, an implantation 222 (e.g., a Zener implantation) is performed to implant p-type dopants to form the Zener region 208, which is illustrated in FIG. 2B. The p-type dopant distribution resulting from the implantation 222 with the photoresist 212 as a mask may be represented with contour lines 232, 234, 236 in view of a bell-shaped profile (e.g., a Gaussian profile illustrated in FIGS. 4A and 4B) of an implanted dopant concentration profile. Namely, the contour line 232 corresponds to locations having the peak concentration of the p-type dopant in the semiconductor substrate 102 as a result of the implantation 222. The contour lines 234, 236 correspond to locations where detectable amounts of the p-type dopant from the implantation 222 cease and/or are dominated by the concentration of p-type dopant of the semiconductor substrate 102 at respective vertical locations away from the peak concentration of the p-type dopant. At any given lateral location, the concentration of the p-type dopant from the implantation 222 increases in a direction vertically from the contour line 234 to the contour line 232, and the concentration of the p-type dopant from the implantation 222 decreases in a direction vertically from the contour line 232 to the contour line 236, as indicated subsequently in FIGS. 4A and 4B.

In the first lateral region 122, the contour line 232 corresponding to the peak concentration is at a uniform depth (e.g., a first depth 412 denoted in FIG. 4A) in the semiconductor substrate 102 due to the full exposure of the semiconductor substrate 102 in the first lateral region 122 by the opening 214 through the photoresist 212. No photoresist is in the first lateral region 122 to block or impede uniform implantation in the semiconductor substrate 102, and hence, the contour line 232 corresponding to the peak concentration (and resulting Zener region 208 including the peak concentration) is uniformly distributed across the first lateral region 122.

In the second lateral region 124, a thickness of the photoresist 212 varies due to the sloped sidewalls 216, which may result in correspondingly varying depths of the peak concentration, and hence the contour line 232 deviates from that of the first lateral region 122. The portion of the implantation 222 that is incident on the sloped sidewalls 216 may have an energy of the implanted ions dissipated through the respective thickness of the photoresist 212 such that the implanted ions (and hence, p-type dopants) are stopped at a depth in the semiconductor substrate 102 that complements the thickness of the photoresist 212 through which the ions are implanted. With the sloped sidewalls 216 beginning at the upper surface of the semiconductor substrate 102 and extending with a constant slope through the second lateral region 124, the depths of the peak concentration (hence, the contour line 232) may be continuous at the first-second transition 132 and continue with a constant slope in the second lateral region 124—e.g., to the upper surface of the semiconductor substrate 102 in some examples.

In the illustrated example, the second-third transition 134 occurs where a concentration of the p-type dopant (such as the concentration at the contour line 236) changes from decreasing in depth according to the slope in the second lateral region 124 to a uniform depth. In this example, the photoresist 212 has a full thickness in the third lateral region 126 that permits some of the p-type dopant to reach the semiconductor substrate 102 (e.g., a portion of the p-type dopant concentration as depicted in FIG. 4C). In some examples, the photoresist 212 may be sufficiently thick to prevent any p-type dopant from reaching the semiconductor substrate 102 in the third lateral region 126. In such examples, the second-third transition 134 may be where the contour line 236 reaches the upper surface of the semiconductor substrate 102.

A p-n junction is formed between the cathode region 104 and the Zener region 208. The p-n junction in the first lateral region 122 is at a depth 242 in the semiconductor substrate 102 (e.g., the first depth 412 illustrated in FIG. 4A). The p-n junction in the second lateral region 124 may vary in depth (e.g., shallower than the depth 242), indicated as varying depth 244 (e.g., including the second depth 414 illustrated in FIG. 4B), depending on at least where the implanted p-type dopant profile intersects the n-type dopant profile of the cathode region 104, as will be described in more detail subsequently. In the illustrated example, the depth 244 includes a peak intersection 152 in the second lateral region 124 where n-type dopant concentration of the cathode region 104 corresponds to the peak concentration of the p-type dopant of the Zener region 208 (as shown by contour line 232). The depth 244 of the p-n junction in the second lateral region 124 may be less than the depth 242 of the p-n junction in the first lateral region 122.

As illustrated, the contour line 232 corresponding to the peak concentration of the p-type dopant profile intersects the cathode region 104 in the second lateral region 124. This intersection may increase tunneling current and lower noise as described herein above. P-type dopant may be in the cathode region 104 in the second lateral region 124 and the third lateral region 126 (e.g., as illustrated in FIGS. 4B and 4C), which is dominated by the concentration of the n-type dopant of the cathode region 104.

FIGS. 3A and 3B illustrate cross-sectional views of a semiconductor device (e.g., the semiconductor device 100 through the cross-section A-A of FIG. 1) for forming a Zener region 308 according to some examples. FIGS. 3A and 3B show the semiconductor device during and following implantation of a p-type dopant for forming a Zener region 308 (e.g., a Zener implantation). Referring to FIG. 3A, the cathode region 104 has been formed in the semiconductor substrate 102. A photoresist 312 is formed over and on the semiconductor substrate 102. In some examples, the photoresist 312 has a thickness in a range from approximately 0.5 μm (e.g., 0.5 μm±10%, 0.5 μm±20%) to approximately 2 μm (e.g., 2 μm±10%, 2 μm±20%). The photoresist 312 has an opening 314 that exposes an upper surface of the semiconductor substrate 102. The opening 314 is defined by sidewalls that have respective lower vertical sidewall portions 316a and upper sloped sidewall portions 316b of the photoresist 312.

The portion of the upper surface of the semiconductor substrate 102 that is fully exposed by the opening 314 corresponds to the first lateral region 122. In this example, the lateral extents of the sidewalls (including the sidewall portions 316a, 316b) define the second lateral region 124. In some examples, the upper sidewall portion 316b accounts for at least 25% of the thickness of the photoresist 312—e.g., uppermost 25%, 50%, 75% of the thickness of the photoresist 312. The third lateral region 126 is the region covered by the full thickness of the photoresist 312. In some examples, if full blocking of dopants in the Zener implantation may be achieved by a partial thickness of the photoresist 312, the third lateral region 126 may expand to include portions of the photoresist 312 forming the upper sloped sidewall portions 316b where the thickness of the photoresist 312 is at or exceeds the thickness to achieve full blocking.

The upper sloped sidewall portions 316b form an angle 318 with the upper surface of the semiconductor substrate 102 (or a plane parallel to the upper surface) interior to the photoresist 312 and form an angle 320 with the upper surface of the semiconductor substrate 102 (or a plane parallel to the upper surface) interior to the opening 314. In some examples, the angle 318 interior to the photoresist 312 may be equal to or less than 80 degrees, and more particularly, in a range from 45 degrees to 80 degrees. In some examples, the angle 320 interior to the opening 314 may be equal to or greater than 100 degrees, and more particularly, in a range from 100 degrees to 135 degrees. The photoresist 312 may be formed by depositing and patterning the photoresist 312 using appropriate photolithography techniques, as described above.

Using the photoresist 312 as a mask, an implantation 322 (e.g., a Zener implantation) is performed to implant p-type dopants to form the Zener region 308, which is illustrated in FIG. 3B. The p-type dopant distribution resulting from the implantation 322 with the photoresist 312 as a mask may be represented with contour lines 332, 334, 336 in view of a bell-shaped profile (e.g., a Gaussian profile illustrated in FIGS. 4A and 4B) of an implanted dopant concentration profile. Namely, the contour line 332 corresponds to locations having the peak concentration of the p-type dopant in the semiconductor substrate 102 as a result of the implantation 322. The contour lines 334, 336 correspond to locations where detectable amounts of the p-type dopant from the implantation 322 cease and/or are dominated by the concentration of p-type dopant of the semiconductor substrate 102 at respective vertical locations away from the peak concentration of the p-type dopant. At any given lateral location, the concentration of the p-type dopant from the implantation 322 increases in a direction vertically from the contour line 334 to the contour line 332, and the concentration of the p-type dopant from the implantation 322 decreases in a direction vertically from the contour line 332 to the contour line 336, as indicated subsequently in FIGS. 4A and 4B.

In the first lateral region 122, the contour line 332 corresponding to the peak concentration is at a uniform depth (e.g., a first depth 412 denoted in FIG. 4A) in the semiconductor substrate 102 due to the full exposure of the semiconductor substrate 102 in the first lateral region 122 by the opening 314 through the photoresist 312. No photoresist is in the first lateral region 122 to block or impede uniform implantation in the semiconductor substrate 102, and hence, the contour line 332 corresponding to the peak concentration (and resulting Zener region 308 including the peak concentration) is uniformly distributed across the first lateral region 122.

In the second lateral region 124, a thickness of the photoresist 312 varies due to the upper sloped sidewall portions 316b, which may result in correspondingly varying depths of the peak concentration as indicated by contour line 332. The portion of the implantation 322 that is incident on the upper sloped sidewall portions 316b may have an energy of the implanted ions dissipated through the respective thickness of the photoresist 312 such that the implanted ions (and hence, p-type dopants) are stopped at a depth in the semiconductor substrate 102 that complements the thickness of the photoresist 312 through which the ions are implanted. The lower vertical sidewall portions 316a may result in a discontinuity of the peak concentration (as indicated by a discontinuity in the contour line 332) in the semiconductor substrate 102 at the first-second transition 132. From this discontinuity in the peak concentration at the first-second transition 132, the depths of the peak concentration (hence, the contour line 332) may be continuous from the first-second transition 132 and continue with a constant slope in the second lateral region 124—e.g., to the upper surface of the semiconductor substrate 102 in some examples.

In the illustrated example, the second-third transition 134 occurs where a concentration of the p-type dopant (such as the concentration at the contour line 336) changes from decreasing in depth according to the slope in the second lateral region 124 to a uniform depth. In this example, the photoresist 312 has a full thickness in the third lateral region 126 that permits some of the p-type dopant to reach the semiconductor substrate 102 (e.g., a portion of the p-type dopant concentration as depicted in FIG. 4C). In some examples, the photoresist 312 may be sufficiently thick to prevent any p-type dopant from reaching the semiconductor substrate 102 in the third lateral region 126. In such examples, the second-third transition 134 may be where the contour line 336 reaches the upper surface of the semiconductor substrate 102.

A p-n junction is formed between the cathode region 104 and the Zener region 308. The p-n junction in the first lateral region 122 is at a depth 342 in the semiconductor substrate 102 (e.g., the first depth 412 illustrated in FIG. 4A). The p-n junction in the second lateral region 124 may vary in depth (e.g., shallower than the depth 342), indicated as varying depth 344 (e.g., including the second depth 414 illustrated in FIG. 4B), depending on at least where the implanted p-type dopant profile intersects the n-type dopant profile of the cathode region 104, as will be described in more detail subsequently. In the illustrated example, the depth 344 includes a peak intersection 152 in the second lateral region 124 where the n-type dopant concentration of the cathode region 104 corresponds to the peak concentration of the p-type dopant of the Zener region 108 (as shown by contour line 332). The depth 344 of the p-n junction in the second lateral region 124 may be less than the depth 342 of the p-n junction in the first lateral region 122.

As illustrated, the contour line 332 corresponding to the peak concentration of the p-type dopant profile intersects the cathode region 104 in the second lateral region 124. This intersection may increase tunneling current and lower noise as described herein above. P-type dopant may be in the cathode region 104 in the second lateral region 124 and the third lateral region 126 (e.g., as illustrated in FIGS. 4B and 4C), which is dominated by the concentration of the n-type dopant of the cathode region 104.

FIGS. 4A, 4B, and 4C are charts illustrating concentrations of p-type dopants that form a Zener region (e.g., Zener region 108, 208, 308) and n-type dopants that form the cathode region (e.g., the cathode region 104) in the first lateral region 122, second lateral region 124, and third lateral region 126, respectively, according to some examples. The x-axis of FIGS. 4A, 4B, and 4C is a depth (in a linear scale) in the semiconductor substrate 102 at a lateral location in the first lateral region 122, second lateral region 124, and third lateral region 126, respectively, and the y-axis is a concentration (in a logarithmic scale).

FIGS. 4A, 4B, and 4C show an n-type dopant profile 402 and a p-type dopant profile 404. The n-type dopants of the n-type dopant profile 402 form the cathode region 104, and the p-type dopant of the p-type dopant profile 404 forms the Zener region (e.g., Zener region 108, 208, 308). The p-type dopant profile 404 has a peak concentration 406, which corresponds to the contour lines 232, 332 described with reference to FIGS. 2B and 3B.

In FIG. 4A representing a lateral location (e.g., at middle location) in the first lateral region 122, a p-n junction is formed at the intersection of the n-type dopant profile 402 and the p-type dopant profile 404 at a first depth 412. The n-type dopant concentration and the p-type dopant concentration at the first depth 412 are substantially the same at a first concentration 422. The intersection at the first depth 412 may be uniform across the first lateral region 122, like the depths 242, 342 in FIGS. 2B and 3B.

In FIG. 4C representing a lateral location in the third lateral region 126, the p-type dopant profile 404 in the semiconductor substrate 102 is translated relative to FIG. 4A to a shallower depth in the semiconductor substrate 102 (e.g., such that the peak concentration 406 is not present). The p-type dopant profile 404 is within and dominated by the n-type dopant profile 402 having the n-type dopant concentration greater than the p-type dopant concentration of the Zener region. Hence, no p-n junction is formed between the Zener region and the cathode region 104 in the third lateral region 126. A p-n junction may be formed between the cathode region 104 and the semiconductor substrate 102 in the third lateral region 126 (e.g., where the n-type dopant concentration is substantially equal to the p-type dopant concentration of the semiconductor substrate 102). The p-type dopant profile 404 and the n-type dopant profile 402 may be at respective uniform depths across the third lateral region 126.

In FIG. 4B representing the peak intersection 152 in the second lateral region 124, the p-type dopant profile 404 in the semiconductor substrate 102 is translated between the depth in FIG. 4A and the depth in FIG. 4C. More generally, throughout the second lateral region 124, as the lateral location moves away from the first lateral region 122 and within the second lateral region 124, the p-type dopant profile 404 is correspondingly translated to shallower depths in the semiconductor substrate 102. This translation in the second lateral region 124 may result in a constant slope of the contour line 232 corresponding to the peak concentration of the p-type dopant as described with respect to FIGS. 2B and 3B. The translation of the p-type dopant profile 404 may result in, as shown in FIG. 4B, the p-n junction between the cathode region 104 and the Zener region (e.g., Zener region 108, 208, 308) being at a second depth 414 in the second lateral region 124 where the peak concentration 406 intersects the n-type dopant profile 402. Accordingly, the n-type dopant concentration and the p-type dopant concentration at the second depth 414 are substantially the same at a second concentration 424 (e.g., the peak concentration 406 of the p-type dopant) greater than the first concentration 422. Further, the second depth 414 in FIG. 4B is shallower or lesser than the first depth 412 in FIG. 4A. In some examples, the first depth 412 may be in a range from 0.15 μm to 0.35 μm, such as 0.25 μm, and the second depth 414 may be in a range from 0.10 μm to 0.30 μm, such as 0.20 μm. In some examples, the first depth 412 may be in a range from 0.75 μm to 1.35 μm, such as 1.05 μm, and the second depth 414 may be in a range from 0.70 μm to 1.30 μm, such as 1.00 μm. The portion of the p-type dopant profile 404 at shallower depths than the second depth 414 overlaps and is dominated by the n-type dopant profile 402. The portion of the n-type dopant profile 402 at deeper depths than the second depth 414 overlaps and is dominated by the p-type dopant profile 404.

Under a reverse bias operating condition, a first depletion width formed at (or around) the p-n junction at the first depth 412 is expected to be greater than a second depletion width formed at (or around) the p-n junction at the second depth 414 due to the less first concentration 422 than the second concentration 424. Accordingly, a first electric field across the first depletion width is expected to be less than a second electric field across the second depletion width, and the reverse bias breakdown characteristics of the semiconductor device 100 (e.g., reverse bias leakage current and/or reverse bias breakdown voltage) may be primarily based on the second lateral region 124. Moreover, as the second concentration 424 may be devised to have the reverse bias breakdown behavior in the second lateral region 124 dominated by tunneling phenomena, e.g., in comparison to the first concentration 422 causing the reverse bias breakdown behavior in the first lateral region 122 dominated by impact ionization phenomena. The tunneling phenomena may be less prone to generate noise than the impact ionization phenomena, and thus, the semiconductor device 100 may exhibit less noisy characteristics during operation.

Although FIG. 4B shows the second concentration 424 as the peak concentration of the p-type dopant profile 404 and the second concentration 424 at the second depth 414 is described to cause the reverse bias breakdown behavior in the second lateral region 124 dominated by tunneling phenomena, the second depth 414 may not be the only location where the tunneling phenomena dominates the reverse bias breakdown. For example, at a concentration 424a that is less than the second concentration 424 (e.g., a concentration 424a equal to 95%, 90%, 85%, 80% of the second concentration 424 or even less) at locations proximate to the second depth 414 (e.g., around the second depth 414, greater than the second depth 414), the reverse bias breakdown behavior may be still dominated by tunneling phenomena. Accordingly, the second lateral region 124 may include a sub-region (e.g., a band including the contour line 232 described with reference to FIG. 2B, a band including the contour line 332 described with reference to FIG. 3B), where the reverse bias breakdown characteristics are dominated by the tunneling phenomena in view of the lateral extent of the sloped sidewalls 216 of the photoresist 212 resulting in varying depth of the p-type dopant profile 404 in the second lateral region 124. In this manner, the semiconductor device 100 can have less noisy reverse bias breakdown characteristics than otherwise possible (e.g., without the sloped sidewalls of the photoresist).

FIG. 5 is a layout view of a semiconductor device 500 according to some examples. The semiconductor device 500 may be a diode. The semiconductor device 500 is in a semiconductor substrate 102. The semiconductor device 500 includes a cathode region 104, an anode region 106, multiple Zener regions 502, 504, and a highly doped region 506. The semiconductor substrate 102, cathode region 104, and anode region 106 are generally as described above.

The Zener regions 502, 504, in some examples, are p-type doped regions in the semiconductor substrate 102. The Zener regions 502, 504 are laterally within the cathode region 104 and are laterally separated from each other. The Zener region 504 laterally surrounds and encircles the Zener region 502. The Zener region 502, as illustrated, is a circular shape in the layout, and the Zener region 504 is an annular ring shape in the layout. The cathode region 104 extends laterally between the Zener regions 502, 504 and laterally surrounds and extends laterally from the Zener region 504. The Zener regions 502, 504 underlie the cathode region 104 in the semiconductor substrate 102, and each extends from the cathode region 104 to a depth in the semiconductor substrate 102. The Zener region 502 forms a first p-n junction with the cathode region 104, and the Zener region 504 forms a second p-n junction with the cathode region 104. As described previously, a peak concentration of the p-type dopant of each Zener region 502, 504 may be controlled to be at various depths in the semiconductor substrate 102. In some examples, the Zener regions 502, 504 are doped with a p-type dopant with a peak concentration in a range from 3×10¹⁸ cm⁻³ to 3×10¹⁹ cm⁻³. Another doping concentration may be implemented. The shape of the Zener regions 502, 504 in a layout may differ in other examples, such as being rectangular (e.g., a square), ovaloid, or another shape. Multiple Zener regions may be implemented, such as in a concentric configuration. In other examples, the relative orientation of Zener regions may also differ, such as by having an array of a given shape in the layout.

FIG. 5 further shows first lateral regions 122, second lateral regions 124, and third lateral regions 126. As described above, a first lateral region 122 is an area of the semiconductor substrate 102 that is fully exposed (e.g., without photoresist blocking) during an implantation process to form the respective Zener region 502, 504. A third lateral region 126 is an area of the semiconductor substrate 102 that has full blocking, to the extent provided, by a photoresist during the implantation process to form the Zener regions 502, 504. A second lateral region 124 is an area of the semiconductor substrate 102 that experiences varying levels of blocking by the photoresist during the implantation process to form the respective Zener region 502, 504.

The respective doping profile of the Zener regions 502, 504 may each be like any of the doping profiles described previously, such as in FIG. 2B or 3B. Having more instances of the second lateral region 124 may increase the presence of the intersections of peak concentrations of p-type dopant concentrations of the Zener regions 502, 504 with the cathode region 104, which may increase tunneling current and decrease noise.

The highly doped region 506, in some examples, is an n-type doped region in the semiconductor substrate 102. The highly doped region 506 laterally surrounds and encircles the cathode region 104. The highly doped region 506 is an annular ring shape around the cathode region 104. The highly doped region 506 extends from an upper surface of the semiconductor substrate 102 to a depth in the semiconductor substrate 102. A concentration of the n-type dopant of the highly doped region 506 is greater than a concentration (e.g., a peak concentration) of the n-type dopant of the cathode region 104. In some examples, the highly doped region 506 is doped with an n-type dopant with a peak concentration in a range from 3×10¹⁹ cm⁻³ to 1×10²¹ cm⁻³. Another doping concentration may be implemented.

FIG. 6 illustrates a cross-sectional view of the semiconductor substrate 102 during implantation of a p-type dopant for forming the Zener regions 502, 504 according to some examples. The cathode region 104 has been formed in the semiconductor substrate 102. A photoresist 612 is formed over and on the semiconductor substrate 102. The photoresist 612 has openings 614, 624 that expose an upper surface of the semiconductor substrate 102. The opening 614 is defined by sloped sidewalls 616 of the photoresist 612, and the opening 624 is defined by sloped sidewalls 626 of the photoresist 612. Each of the openings 614, 624 with respective sidewalls may be like any of the openings 214, 314 described above.

Using the photoresist 612 as a mask, an implantation 622 is performed to implant p-type dopants to form the Zener regions 502, 504. The opening 614 corresponds with the Zener region 502, and the opening 624 corresponds with the Zener region 504. The implantation 622 with the photoresist 612 as a mask forms a doping profile (e.g., including peak concentration, continuity of a concentration, slope of a concentration, and depths) as described above with respect to a corresponding photoresist 212, 312 described above.

FIG. 7 through FIG. 10 are respective cross-sectional views of a semiconductor device in intermediate stages of manufacturing according to some examples. The example illustrated by FIGS. 7 through 10 shows a general manufacturing method such that a semiconductor device having any of the components described above may be manufactured. Various components and/or processing operations may be included or omitted in various manufacturing methods.

Referring to FIG. 7, a cathode region 104 is formed in a semiconductor substrate 102. The semiconductor substrate 102 may be as described above. The cathode region 104 may be formed by forming a photoresist 702 with an opening 704 corresponding to the cathode region 104 over the semiconductor substrate 102. The photoresist 702 may be formed by appropriate photolithography techniques. Using the photoresist 702 as a mask, an implantation 712 is performed to implant n-type dopants into the semiconductor substrate 102, thereby forming the cathode region 104. The dopant and concentration of the dopant for the cathode region 104 may be as described above. The photoresist 702 may thereafter be removed, such as by an ashing process.

Referring to FIG. 8, optionally, a highly doped region 802 (e.g., highly doped region 506 in FIG. 5) is formed in the semiconductor substrate 102. The highly doped region 802 may be formed by forming a photoresist 812 with an opening 814 corresponding to the highly doped region 802 over the semiconductor substrate 102. The photoresist 812 may be formed by appropriate photolithography techniques. Using the photoresist 812 as a mask, an implantation 822 is performed to implant n-type dopants into the semiconductor substrate 102, thereby forming the highly doped region 802. The dopant and concentration of the dopant for the highly doped region 802 may be as described above with respect to the highly doped region 506. The photoresist 812 may thereafter be removed, such as by an ashing process.

Referring to FIG. 9, a Zener region is formed in the semiconductor substrate 102. In the illustrated example, the Zener region is the Zener region 208 of FIG. 2B. In such examples, the Zener region 208 may be formed as described above with respect to FIGS. 2A and 2B (e.g., using the photoresist 212 with an opening 214 having sloped sidewalls 216 as a mask for an implantation 222). In other examples, the Zener region may be the Zener region 308 of FIG. 3B, which may be formed as described above with respect to FIGS. 3A and 3B. In other examples, the Zener region may include multiple Zener regions 502, 504, which may be formed as described above with respect to FIG. 6. Other configurations of a Zener region may be implemented.

Referring to FIG. 10, an anode region 106 is formed in a semiconductor substrate 102. The anode region 106 may be formed by forming a photoresist 1002 with an opening 1004 corresponding to the anode region 106 over the semiconductor substrate 102. The photoresist 1002 may be formed by appropriate photolithography techniques. Using the photoresist 1002 as a mask, an implantation 1012 is performed to implant p-type dopants into the semiconductor substrate 102, thereby forming the anode region 106. The dopant and concentration of the dopant for the anode region 106 may be as described above. The photoresist 1002 may thereafter be removed, such as by an ashing process.

Although various examples have been described in detail, it should be understood that various changes, substitutions, and alterations can be made therein without departing from the scope defined by the appended claims.

What is claimed is:

1. A semiconductor device, comprising:
a first doped region in a semiconductor substrate, the first doped region being doped with a first conductivity type dopant, the first doped region being across a first lateral region and a second lateral region; and
a second doped region in the semiconductor substrate, the second doped region being doped with a second conductivity type dopant opposite from the first conductivity type dopant, the first doped region and the second doped region forming a p-n junction, the second doped region underlying the first doped region in the first lateral region, a peak concentration of the second conductivity type dopant being at a uniform depth across the first lateral region, the peak concentration of the second conductivity type dopant intersecting the first doped region in the second lateral region at a lateral distance from a transition between the first lateral region and the second lateral region.

2. The semiconductor device of claim 1, wherein the p-n junction in the first lateral region is at a first depth in the semiconductor substrate, and the p-n junction where the peak concentration intersects the first doped region in the second lateral region is at a second depth in the semiconductor substrate, the first depth being deeper in the semiconductor substrate than the second depth.

3. The semiconductor device of claim 2, wherein the first depth is in a range from 0.15 μm to 0.35 μm from an upper surface of the semiconductor substrate, and the second depth is in a range from 0.10 μm to 0.30 μm from the upper surface of the semiconductor substrate.

4. The semiconductor device of claim 2, wherein the first depth is in a range from 0.75 μm to 1.35 μm from an upper surface of the semiconductor substrate, and the second depth is in a range from 0.70 μm to 1.30 μm from the upper surface of the semiconductor substrate.

5. The semiconductor device of claim 1, wherein a concentration of the second conductivity type dopant at the p-n junction in the first lateral region is less than the peak concentration.

6. The semiconductor device of claim 1, wherein the lateral distance is aligned with a radius of the first lateral region, the lateral distance being in a range between 0.01 μm and 1.8 μm.

7. The semiconductor device of claim 1, wherein the peak concentration is continuous from a location in the first lateral region to a location in the second lateral region.

8. The semiconductor device of claim 1, wherein the peak concentration is discontinuous from a location in the first lateral region to a location in the second lateral region.

9. The semiconductor device of claim 1, wherein the peak concentration varies in depth in the second lateral region with a slope equal to or less than 5.67 in a direction away from the transition between the first lateral region and the second lateral region.

10. The semiconductor device of claim 9, wherein the slope extends throughout at least a portion of the second lateral region.

11. The semiconductor device of claim 1, wherein the p-n junction is a first p-n junction, the semiconductor device further comprising:
a third doped region in the semiconductor substrate, the third doped region being doped with the second conductivity type dopant, the first doped region and the third doped region forming a second p-n junction, the third doped region underlying the first doped region in the first lateral region and laterally separated from the second doped region.

12. The semiconductor device of claim 11, wherein the third doped region is annular and laterally encircles the second doped region.

13. The semiconductor device of claim 1, wherein the first doped region further extends into a third lateral region, the second doped region not underlying the first doped region in the third lateral region.

14. The semiconductor device of claim 1, further comprising a highly doped region in the semiconductor substrate, the highly doped region being doped with the first conductivity type dopant, the highly doped region being annular and laterally encircles the first doped region.

15. The semiconductor device of claim 1, wherein:
the first conductivity type dopant is an n-type dopant;
the second conductivity type dopant is a p-type dopant;
the first doped region is a cathode region; and
the second doped region is a Zener region.

16. A semiconductor device, comprising:
a first doped region in a semiconductor substrate, the first doped region being doped with a first conductivity type dopant, the first doped region being across a first lateral region and a second lateral region; and
a second doped region in the semiconductor substrate, the second doped region being doped with a second conductivity type dopant opposite from the first conductivity type dopant, the second doped region underlying the first doped region in the first lateral region, wherein:
a peak concentration of the second conductivity type dopant is uniform in depth in the semiconductor substrate across the first lateral region;
a first concentration of the second conductivity type dopant changes in depth in the semiconductor substrate throughout the second lateral region such that the peak concentration of the second conductivity type dopant decreases in depth in the semiconductor substrate in the second lateral region and in a direction laterally away from the first lateral region;
the first lateral region has a radius; and
the second lateral region has a lateral dimension aligned with the radius, the lateral dimension being equal to or greater than 0.02 μm.

17. The semiconductor device of claim 16, wherein the first concentration of the second conductivity type dopant changes in depth in the semiconductor substrate throughout the second lateral region and in the direction laterally away from the first lateral region at a slope equal to or less than 5.67.

18. The semiconductor device of claim 16, wherein the first doped region and the second doped region form a p-n junction, the peak concentration of the second conductivity type dopant intersecting the first doped region in the second lateral region at a lateral distance from a transition between the first lateral region and the second lateral region.

19. The semiconductor device of claim 18, wherein the p-n junction in the first lateral region is at a first depth in the semiconductor substrate, and the p-n junction where the peak concentration intersects the first doped region in the second lateral region is at a second depth in the semiconductor substrate, the first depth being greater in the semiconductor substrate than the second depth.

20. The semiconductor device of claim 18, wherein a second concentration of the second conductivity type dopant at the p-n junction in the first lateral region is less than the peak concentration.

21. The semiconductor device of claim 16, wherein the peak concentration is continuous from a location in the first lateral region to a location in the second lateral region.

22. The semiconductor device of claim 16, wherein the peak concentration is discontinuous from a location in the first lateral region to a location in the second lateral region.

23. The semiconductor device of claim 16, further comprising a third doped region in the semiconductor substrate, the third doped region being doped with the second conductivity type dopant, the third doped region underlying the first doped region in the first lateral region and laterally separated from the second doped region.

24. The semiconductor device of claim 23, wherein the third doped region is annular and laterally encircles the second doped region.

25. A method, comprising:
forming a first doped region in a semiconductor substrate, the first doped region being doped with a first conductivity type dopant; and
forming a second doped region in the semiconductor substrate, the second doped region being doped with a second conductivity type dopant opposite from the first conductivity type dopant, the second doped region underlying the first doped region, forming the second doped region comprising:
forming a photoresist over the semiconductor substrate, the photoresist having a first opening defined at least in part by a first sidewall, at least a portion of the first sidewall being sloped at a first angle of 80 degrees or less to a plane parallel to an upper surface of the semiconductor substrate; and
implanting the second conductivity type dopant into the semiconductor substrate using the photoresist as a mask.

26. The method of claim 25, wherein the first sidewall is sloped from a bottom surface of the photoresist to a top surface of the photoresist.

27. The method of claim 25, wherein the first sidewall has a lower vertical sidewall portion and an upper sloped sidewall portion.

28. The method of claim 25, wherein forming the second doped region further forms a third doped region in the semiconductor substrate, the third doped region being doped with the second conductivity type dopant, the third doped region underlying the first doped region, the photoresist having a second opening laterally separated from the first opening, the second opening being defined at least in part by a second sidewall, at least a portion of the second sidewall being sloped at a second angle of 80 degrees or less to the plane parallel to the upper surface of the semiconductor substrate.

29. The method of claim 25, wherein the first doped region is a cathode region of a diode, and the second doped region is a Zener region.

30. The method of claim 25, wherein the first angle is greater than or equal to 45 degrees.
